(19) United States
(12) Patent Application Publication
(10) Pub. No.: US 2020/0176338 A1
(43) Pub. Date: Jun. 4, 2020

(54) METHOD OF MONITORING LIGHT EMISSION, SUBSTRATE PROCESSING METHOD, AND SUBSTRATE PROCESSING APPARATUS

(71) Applicant: TOKYO ELECTRON LIMITED, Tokyo (JP)

(72) Inventor: Kazuaki NISHIMURA, Nirasaki City (JP)

(21) Appl. No.: 16/700,458

(22) Filed: Dec. 2, 2019

(30) Foreign Application Priority Data
Dec. 4, 2018 (JP) 2018-227102

(51) Int. Cl. H01L 21/66; H01L 21/311; G01N 21/75

(52) U.S. Cl. CPC H01L 22/26; G01N 21/75; H01L 21/31116

(57) ABSTRACT

A method of monitoring light emission of SiF in a reaction that forms a SiF₄ gas includes: guiding an exhaust gas, which includes the SiF₄ gas formed in the reaction, together with an Ar gas to a light emission monitoring unit; and monitoring the light emission of SiF in a state in which a measurement environment of the light emission monitoring unit is set to be an Ar gas atmosphere.

### CROSS-REFERENCE TO RELATED APPLICATION

This application is based upon and claims the benefit of priority from Japanese Patent Application No. 2018-227102, filed on Dec. 4, 2018, the entire contents of which are incorporated herein by reference.

### TECHNICAL FIELD

The present disclosure relates to a method of monitoring light emission, a substrate processing method, and a substrate processing apparatus.

### BACKGROUND

As a method for chemically removing a silicon oxide film, a chemical oxide removal (COR) process that uses a HF gas and a NH₃ gas is known (Patent Documents 1 and 2). In the COR process, ammonium fluorosilicate (AFS) is formed as a reaction product. It is necessary to decompose the AFS after the COR process. Here, as a method of detecting an end point of the decomposition process, a method of introducing an exhaust gas including SiF₄, which is formed as the AFS is decomposed, into an analysis unit and exciting the exhaust gas with plasma to analyze light emission of SiF is known (Patent Document 3).

### PRIOR ART DOCUMENTS

### Patent Documents

Patent Document 1: Japanese laid-open publication No. 2005-39185

Patent Document 2: Japanese laid-open publication No. 2008-160000

Patent Document 3: Japanese patent No. 4792369

### SUMMARY

An aspect of the present disclosure provides a method of monitoring light emission of SiF in a reaction that forms a SiF₄ gas including: guiding an exhaust gas, which includes the SiF₄ gas formed in the reaction, together with an Ar gas to a light emission monitoring unit; and monitoring the light emission of SiF in a state in which a measurement environment of the light emission monitoring unit is set to be an Ar gas atmosphere.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating a substrate processing method according to a first embodiment;

FIG. 2 is a flowchart illustrating another example of the substrate processing method according to the first embodiment;

FIG. 3 is a view illustrating a result of a light emission analysis on SiF performed by using a N₂ gas as a purge gas, for each cases of forming AFS on a SiO₂ film and forming no AFS;

FIG. 4 is a view illustrating a result of a light emission analysis on SiF performed by using an Ar gas as a purge gas, for each cases of forming AFS on a SiO₂ film and forming no AFS;

FIG. 5 is a view illustrating a result of a light emission analysis on OH, for each cases of forming AFS on a SiO₂ film and forming no AFS;

FIG. 6 is a view illustrating a result of a spectroscopic analysis on SiF performed by purging a chamber with an Ar gas and/or a N₂ gas after performing a COR process using a HF gas and a NF₃ gas and performing a vacuum-evacuation process in a COR apparatus;

FIG. 7 is a view illustrating a result of a spectroscopic analysis on SiF performed by purging a chamber with a 100% Ar gas after performing a COR process using a HF gas and a NF₃ gas and performing a vacuum-evacuation process for various times in a COR apparatus, while a temperature of a substrate was set to be 100 degrees C. and 105 degrees C.;

FIG. 8 is a view illustrating a result of a spectroscopic analysis on SiF performed by purging a chamber with a 100% Ar gas after performing a vacuum-evacuation process for various times, which include shorter times than that used in FIG. 7, while a temperature of a substrate was set to be 105 degrees C.;

FIG. 9 is a flowchart illustrating a substrate processing method according to a second embodiment;

FIG. 10 is a flowchart illustrating a substrate process method according to a third embodiment;

FIG. 11 is a schematic diagram illustrating an example of a processing system used for implementation of the substrate processing methods according to the embodiments;

FIG. 12 is a sectional view illustrating a. COR apparatus; and

FIG. 13 is a sectional view illustrating a PHT apparatus.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments will be described with reference to the accompanying drawings.

### <Details and Outline>

First, details and an outline of a method of detecting an end point of an AFT decomposition process according to embodiments of the present disclosure will be described.

In the related art, a COR process that chemically etches a silicon oxide-based material such as a SiO₂ film uses a HF gas and a NH₃ gas as an etching gas. In the COR process, the HF gas and the NH₃ gas are adsorbed to a SiO₂ film and are reacted with SiO₂ as illustrated in Formula (1) in a COR apparatus, whereby (NH₄)₂SiF₆(AFS) as a solid reaction product is formed. The formed AFS is heated in the COR apparatus or a separate heating apparatus (a PHT apparatus), such that the AFS is sublimated by a reaction as illustrated in Formula (2).

6HF+6NH₃+SiO₂→2H₂O+4NH₃+(NH₄)₂SiF₆ (1)

(NH₄)₂SiF₆→2NH₃+SiF₄+2HF (2)

When the reaction of Formula (2) is incomplete, the residual AFS has bad influences on a device. Thus, it is necessary to confirm that the AFS is completely sublimated.

Patent Document 1 discloses provision of an analysis unit which introduces an exhaust gas from a chamber of a PHT apparatus, excites the exhaust gas by plasma, diffracts light emission of atoms or excited atoms, and measures intensity of the diffracted light by a light emission analyzer. In the PHT apparatus, a decomposition gas such as a NH₃ gas, a SiF₄ gas, and a HF gas according to Formula (2) is formed, and is exhausted together with a N₂ gas that is a purge gas. Then, the exhaust gas is introduced into a container of the analysis unit by using the N₂ gas, which is a purge gas, as a carrier gas, and concentration of the exhaust gas is measured through a light emission analysis. In the PHT apparatus, formation of the decomposition gas is stopped when the AFS is completely decomposed. Thus, in Patent Document 1, an end point of a decomposition process of the AFS is detected by monitoring light emission of the decomposition gas in the exhaust gas.

However, it was confirmed that, when the N₂ gas is used as a purge gas, that is, a carrier gas of the analysis unit as in Patent Document 1, it is substantially impossible to observe a light emission peak caused by a SiF₄ gas that is a decomposition gas with the analysis unit.

Although light emission of an OH component obtained by decomposing and exciting H₂O contained in the AFS in plasma can be observed even when the N₂ gas is used as a carrier gas, it is difficult to delaminate H₂O because H₂O is adsorbed to the chamber. Further, since H₂O contained in the AFS cannot be separated from H₂O due to an environment, there is a difficulty in sensitivity or responsiveness. In particular, the OH component has a fundamental problem that the OH component is neither a component of the AFS nor a component derived from the AFS.

Accordingly, as a result of review, it was confirmed that light emission of SiF formed by exciting a SiF₄ gas by plasma can be observed by using an Ar gas, instead of a conventional N₂ gas, as a carrier gas of the analysis unit.

Similarly, even when SiF₄ is formed in an etching reaction when a silicon-containing film is etched by a fluorine-containing gas, light emission of the SiF can be observed by using an Ar gas as a carrier gas.

That is, when light emission of SiF is monitored in a reaction that forms a SiF₄ gas, an exhaust gas of a decomposition reaction or an etching reaction of a reaction product is guided to a light emission monitoring unit together with an Ar gas, and the light emission of SiF is monitored in a state in which a measurement environment is set to an Ar gas atmosphere. By setting the measurement environment to the Ar gas atmosphere, the light emission of SiF obtained by exciting SiF₄ in the decomposition gas by plasma can be clearly detected, and the light emission of SiF can be monitored with a high precision. Accordingly, for example, an end point of the decomposition reaction or the etching reaction of the reaction product can be detected with a high precision.

### DETAILED EMBODIMENTS

Next, detailed embodiments will be described.

### First Embodiment

First, a first embodiment will be described.

In the present embodiment, an example of performing a COR process and an AFS removal (decomposition) process with a COR apparatus and detecting an end point of the removal process of the AFS will be described.

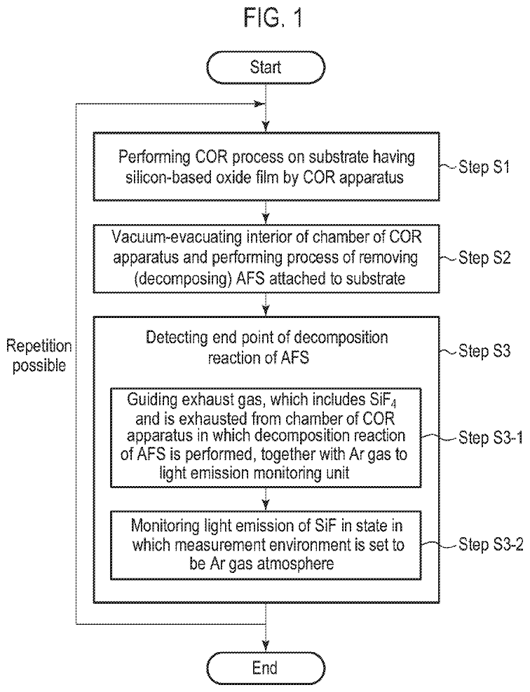

FIG. 1 is a flowchart illustrating a substrate processing method according to the first embodiment.

First, a COR process is performed on a substrate having a silicon-based oxide film, typically, a silicon oxide film (a SiO₂ film) as a silicon-containing film that is an etching target, by a COR apparatus (step S1).

The substrate is not particularly limited, and a semiconductor wafer (hereinafter, simply, referred to as a wafer), the representative of which is a silicon wafer, is an example of the substrate.

In the R process, a HF gas and a NH₃ gas are adsorbed to a surface of the silicon oxide film, and react with the silicon oxide film as in Formula (1), thereby forming AFS.

In the present embodiment, a pressure of the COR process may be set to be in a range of 2.666 to 399.9 Pa (20 to 3000 mTorr), and a temperature of the substrate may be set to be in a range of 20 to 130 degrees C.

Next, an interior of a chamber of the COR apparatus is vacuum-evacuated (complete suction), and a removal (decomposition) process of the AFS attached to the substrate, which is represented in Formula (2), is performed (step S2).

The decomposition process of the AFS at this time is performed at a temperature that is equal to or higher than the temperature in the COR process. By the vacuum-evacuation, a decomposition gas formed by decomposing the AFS is discharged from the chamber.

Next, an end point of the decomposition reaction of the AFS is detected by monitoring light emission of SiF using a light emission monitoring unit installed in an exhauster of the chamber of the COR apparatus (step S3).

The end point detection is performed by a process (step S3-1) of guiding an exhaust gas, which includes a SiF₄ gas and is a gas exhausted from the chamber of the COR apparatus in which the decomposition reaction of the AFS is performed, together with an Ar gas into the light emission monitoring unit, and a process (step S3-2) of monitoring light emission of SiF in a state in which a measurement environment is set to be an Ar gas atmosphere. In detail, the Ar gas is used as a purge gas of the chamber, and the exhaust gas is guided into a container of the light emission monitoring unit by using the Ar gas as a carrier gas of the light emission monitoring unit. Then, the guided gas is excited by plasma and a light emission analysis of the excited gas is performed. By setting the measurement environment to be the Ar gas atmosphere as described above, the t emission of SiF formed by exciting the SiF₄ gas in the decomposition gas, which is included in the exhaust gas, by plasma can be monitored, and the end point can be detected with a high precision.

When a part of the AFS remains without being decomposed, the SiF₄ gas is discharged and a light emission of SiF is detected. On the contrary, when the AFS is substantially completely decomposed, the SiF₄ gas is hardly discharged, and the light emission of SiF is hardly detected. Accordingly, by confirming that intensity of the light emission of SiF is equal to or less than a threshold or there is no light emission of SiF, completion of the decomposition reaction of the AFS can be detected.

The end point detection may be performed by recognizing a time until the AFS is completely decomposed in advance, and monitoring the light emission of SiF after lapse of the time or lapse of the time plus α to confirm that the intensity of the light emission of SiF is equal to or less than the threshold or there is no light emission of SiF. When the light emission of SiF of equal to or greater than the threshold is detected at the time of the monitoring, for example, a countermeasure of changing a condition or the like may be performed.

Steps S1 to S3 may be repeated a plurality of times according to an amount of the silicon oxide film to be etched. In this case, the end point detection in step S3 may not be performed at all timings, and may be performed at arbitrary timings.

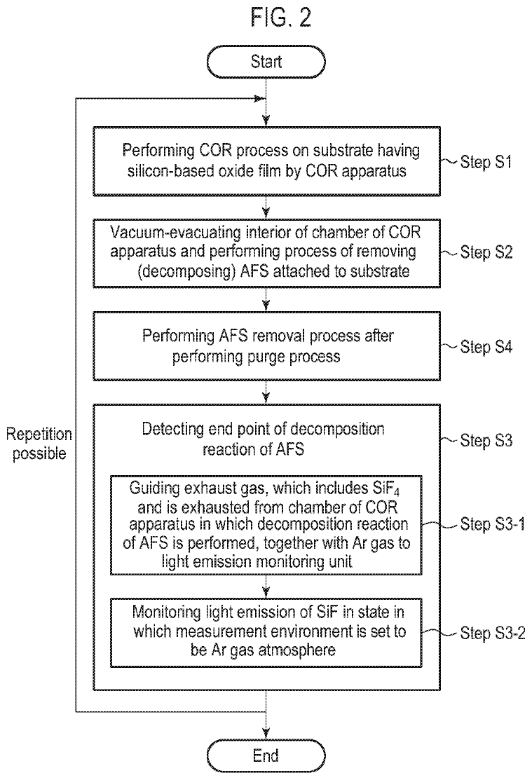

As illustrated in FIG. 2, after the vacuum-evacuation of step S2, the removal process of the AFS may be performed after a purge process of purging the chamber with a purge gas (step S4), and the end point detection in step S3 may be performed after step S4. The removal process of the AFS is expedited by the purge process. When the Ar gas is used in step S4, step S3 may be performed immediately after step S4 is completed. Steps S1, S2, S4, and S3 may be repeated a plurality of times according to an amount of the silicon oxide film to be etched. However, even in this case, the end point detection in step S3 may not be performed at all timings, and may be performed at arbitrary timings.

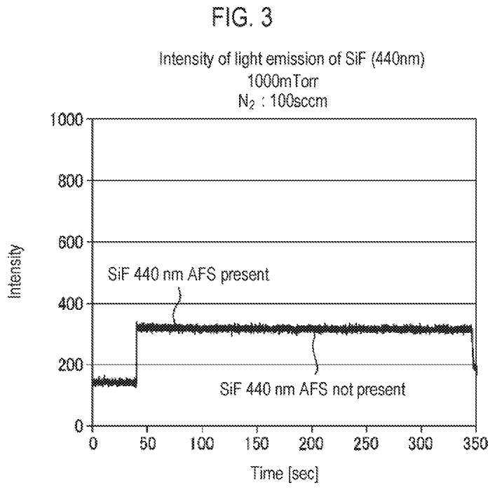

In the related art, the removal process of the AFS is performed by a PHT apparatus using a N₂ gas as a purge gas. In this case, the light emission of SiF is not observed even when a light emission analysis is performed on a decomposition gas including a SiF₄ gas which is formed by decomposing AFS. Actually, when AFS was formed on a SiO₂ film and a light emission analysis of SiF was performed by using a N₂ gas as a purge gas, as illustrated in FIG. 3, the light emission of SiF was hardly observed similarly to a case in which AFS is not present.

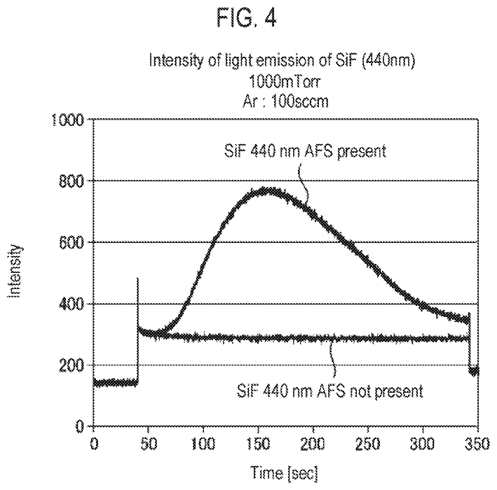

On the contrary, when AFS was formed on a SiO₂ film and a light emission analysis of SiF was performed by using an Ar gas as a purge gas, as illustrated in FIG. 4, the intensity of the light emission of SiF having a wavelength of 440 nm clearly increased.

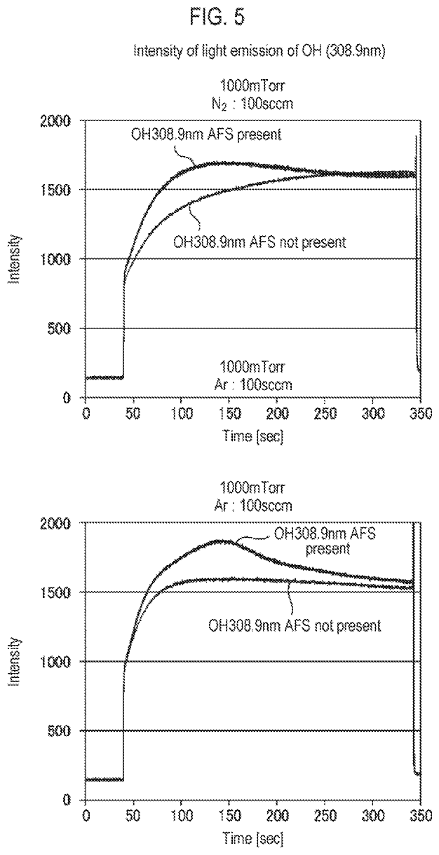

As illustrated in FIG. 5, in both of the cases in which a N₂ gas was used as a purge gas and in which an Ar gas was used as a purge gas, the light emission (308.9 nm) of an OH component obtained by decomposing and exciting H₂O included in the AFS by plasma was observed. However, as illustrated in FIG. 5, the responsiveness and sensitivity were low.

A measurement environment for a light emission analysis may be an Ar gas atmosphere in which a volume % of the Ar gas is greater than 87%. That is, the purge gas may include an Ar gas having a volume % greater than 87%, and the carrier gas of the light emission monitoring unit may be the Ar gas having the volume % greater than 87%. More specifically, only an Ar gas (100% Ar) may be used. When gases other than the Ar gas are included in the Ar gas measurement environment, the intensity of the light emission of SiF significantly decreases, and when the gases other than the Ar gas become 13% or more, it becomes difficult to detect the intensity of the light emission of SiF.

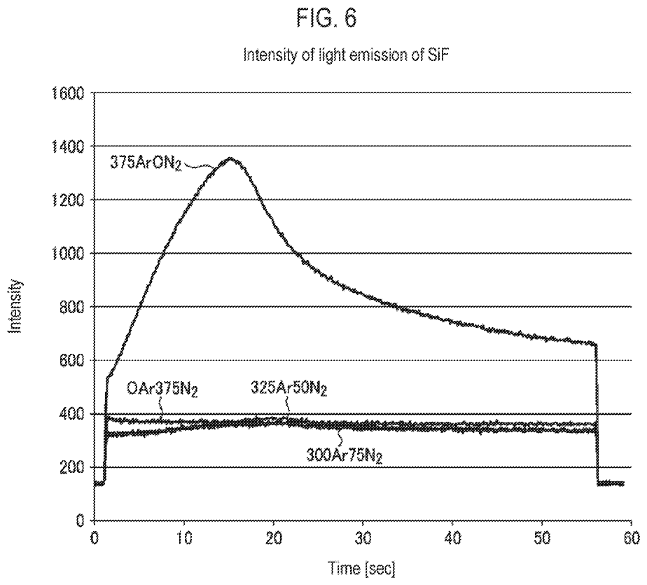

FIG. 6 is a view illustrating a result of a spectroscopic analysis on SiF performed by purging a chamber with an Ar gas and/or a N₂ gas after performing a COR process using a HF gas and a NF₃ gas and performing a vacuum-evacuation process in a COR apparatus.

Here, a temperature of the substrate (a temperature of a stage) was set to be 20 to 130 degrees C. The COR (etching) process was performed under a condition in which a pressure was set to be 20 to 3000 mTorr, flow rates of HF/NH₃/Ar were set to be 10 to 2000/10 to 2000/10 to 2000 sccm, and a time was set to be 2 to 100 seconds. A time for the vacuum-evacuation (complete suction) was set to be 2 seconds, After the chamber was purged at 2000 mTorr for 10 seconds, the light emission of SiF was monitored. By performing the COR (etching) process under the same condition, conditions in the processes of monitoring the light emission of SiF were compared. As the purge gas, flow rates of Ar/N₂ were set to be 375/0 sccm (100% Ar), 325/50 sccm (N₂: 13.3%), 300/75 sccm (N₂: 20%), and 0/375 sccm (100% N₂) were used, respectively.

As illustrated in FIG. 6, even when an amount of the N₂ gas in the purge gas was as small as about 13%, the light emission of SiF extremely decreased. From this, it can be confirmed that the measurement environment of the light emission monitoring unit may be an environment in which the amount of the Ar gas is greater than 87%, and more specifically, may be the Ar gas only.

When the end point detection in step S3 is performed, by monitoring the light emission of SiF in the measurement environment including the Ar gas only (100% Ar), the end point may be detected with a high sensitivity.

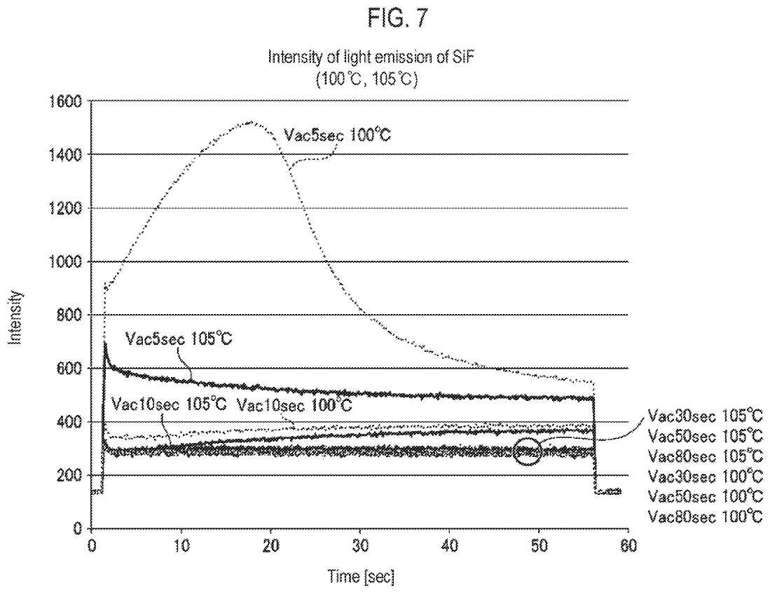

FIG. 7 is a view illustrating a result of a spectroscopic analysis on SiF performed by purging a chamber with an Ar gas only (100% Ar gas) after performing a COR process using a HF gas and a NH₃ gas and performing a vacuum-evacuation process for various times in a COR apparatus, while a temperature of a substrate (a temperature of a stage) was set to be 100 degrees C. and 105 degrees C.;

Here, the COR process was performed under a condition in which a pressure was set to be 20 to 3000 mTorr, flow rates of HF/NH₃/Ar were set to be 10 to 2000/10 to 2000/10 to 2000 sccm, a time was set to be 2 to 100 seconds. Times for the vacuum-evacuation process (Vac) were set to be 5, 10, 30, 50, and 80 seconds. The chamber was purged at 2000 mTorr for 10 seconds, and then the light emission of SiF was monitored.

As illustrated in FIG. 7, it was confirmed that in the vacuum-evacuation process of 5 seconds at the temperatures of the stage of 100 degrees C. and 105 degrees C., a great difference in the light emission of SiF was observed, and a difference in sublimation amounts (decomposition amounts) of the AFS according to a difference in the conditions could be recognized with a high sensitivity. Further, when the time for the vacuum-evacuation process was 30 seconds or more, the light emission of SiF was hardly observed regardless of the temperature. This is because most of SiF was purged out before the monitoring.

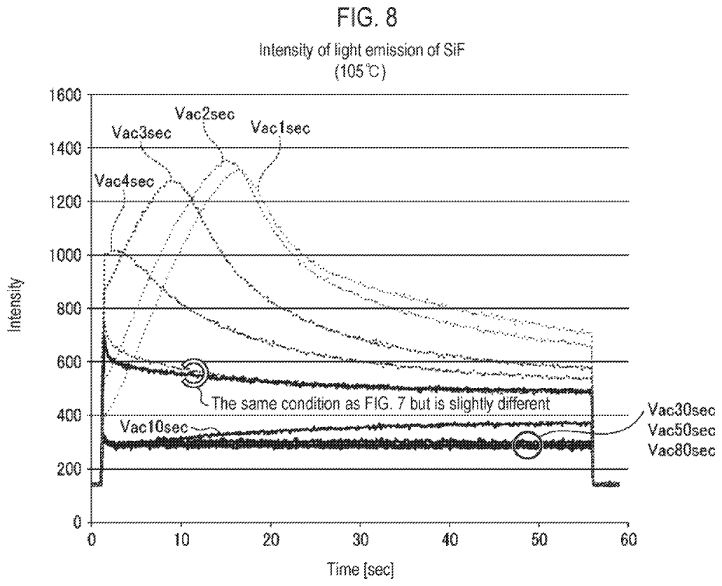

FIG. 8 is a view illustrating a result of a spectroscopic analysis on SiF performed by purging a chamber with an Ar gas only (100% Ar) gas after performing a vacuum-evacuation process for various times, which include shorter times than that used in FIG. 7, while a temperatures of a substrate (a temperature of a stage) was set to be 105 degrees C.

Here, the vacuum-evacuation process was also performed for 1, 2, 3, and 4 seconds, and the conditions for the COR process and the purge process were set to be the same as that of FIG. 7.

As illustrated in FIG. 8, it was confirmed that when the temperature of the stage was set to be 105 degrees C., the light emission of SiF was more clearly observed in the cases of the shorter vacuum-evacuation times of 1, 2, 3, and 4 seconds, and the decomposition reaction of AFS was detected at a higher sensitivity. In FIG. 8, as in FIG. 7, the light emission of SiF was hardly observed in the cases of the vacuum-evacuation time of 30 seconds or more, because most of SiF was purged out before the monitoring.

### Second Embodiment

Next, a second embodiment will be described.

The present embodiment will be explained with an example of performing a COR process by a COR apparatus, performing an AFS removal (decomposition) process by a PHI apparatus, and then detecting an end point of the removal process of the AFS.

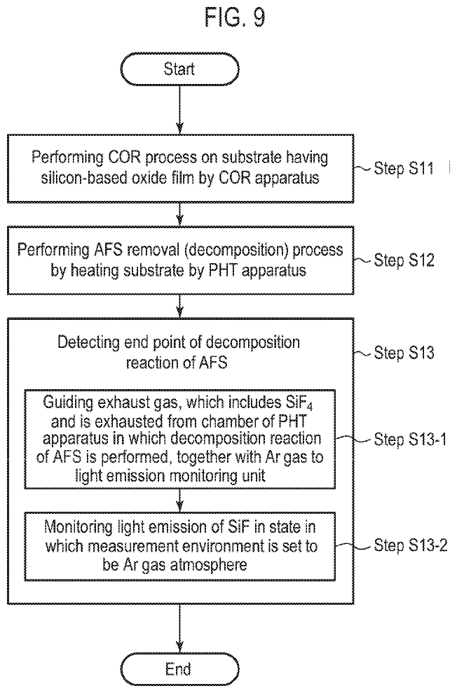

FIG. 9 is a flowchart illustrating a substrate processing method according to the second embodiment.

First, a COR process is performed on a substrate having a silicon oxide film (a SiO₂ film) as a silicon-containing film that is an etching target, by a COR apparatus (step S11).

In the present embodiment, the substrate is not particularly limited, and a wafer is an example of the substrate.

In the COR process, as in the first embodiment, a HF gas and a NH₃ gas are adsorbed to a surface of the silicon oxide film in a chamber, and react with a silicon oxide film as in Formula (I), thereby forming AFS.

In the present embodiment, a pressure of the COR process may be set to be in a range of 2.666 to 399.9 Pa (20 to 3000 mTorr), and a temperature of the substrate may be set to be in a range of 20 to 130 degrees C.

Next, the substrate to which the AFS is attached is heated by the PHT apparatus and a removal (decomposition) process of the AFS is performed as in a reaction of Formula (2) (step S12).

At this time, the AFS is decomposed in a state in which the pressure of the chamber is set to be 1.333 to 666.6 Pa (10 to 5000 mTorr) and the heating temperature of the substrate is set to be 100 to 300 degrees C., and the decomposition gas is discharged from the chamber of the PHT apparatus by supplying the purge gas.

Next, the end point of the decomposition reaction of the AFS is detected by monitoring light emission of SiF by a light emission monitoring unit installed in an exhauster of the chamber of the PHT apparatus (step S13).

The end point detection is performed by a process (step S13-1) of guiding an exhaust gas, which includes a SiF₄ gas and is a gas exhausted from the chamber of the PHI apparatus in which the decomposition reaction of the AFS is performed, together with an Ar gas into the light emission monitoring unit, and a process (step S13-2) of monitoring light emission of SiF in a state in which a measurement environment is to be an Ar gas atmosphere. In detail, the Ar gas is used as a purge gas of the chamber, and the exhaust gas is guided into a container of the light emission monitoring unit by using the Ar gas as a carrier gas of the light emission monitoring unit. Then, the guided gas is excited by plasma and a light emission analysis of the excited gas is performed. By setting the measurement environment to be the Ar gas atmosphere as described above, the light emission of SiF formed by exciting the SiF₄ gas in the decomposition gas, which is included in the exhaust gas, by plasma can be monitored.

When a part of the AFS remains without being decomposed, the SiF₄ gas is discharged and a light emission of the SiF is detected. On the contrary, when the AFS is substantially completely decomposed, the SiF₄ gas is hardly discharged, and the light emission of SiF is hardly detected. Accordingly, by confirming that intensity of the light emission of SiF is equal to or less than a threshold or there is no light emission of SiF, completion of the decomposition reaction of the AFS can be detected.

In the end point detection, the light emission of SiF is continuously monitored, and a time point at which the intensity of the light emission becomes equal to or less than the threshold or a time point at which the intensity of the light emission becomes zero may be determined as the end point. The monitoring may be started at the start of the heating by the PHT apparatus, or may be started after lapse of a desired period of time from the start of the heating by the PHI apparatus. Alternatively, the end point detection may be performed by recognizing a time until the AFS is completely decomposed in advance, and monitoring the light emission of SiF after lapse of the time or lapse of the time plus a to confirm that the intensity of the light emission of SiF becomes equal to or less than the threshold or becomes zero. When the light emission of SiF is detected at the time of the monitoring time, a countermeasure of, for example, extending the heating time may be carried out.

When the light emission of SiF for use in detecting the end point is not monitored, the purge gas of the PHI apparatus may be a N₂ gas.

Similarly to the first embodiment, a gas having a volume % of an Ar gas greater than 87% may be used as a carrier gas for use in the light emission analysis, and the environment under which the light emission is measured may; be an Ar gas atmosphere in which the volume % of the Ar gas is greater than 87%. More specifically, the Ar gas only (100% Ar) may be used.

### Third Embodiment

Next, a third embodiment will be described.

In the present embodiment, an example of detecting an end point when a Si-containing film is etched by a fluorine-containing gas will be described.

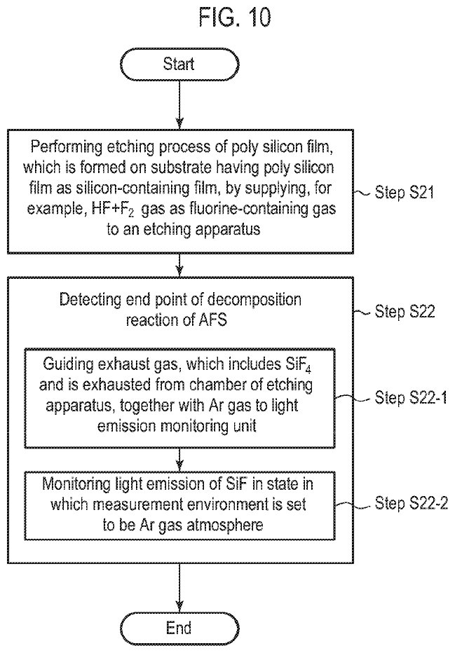

FIG. 10 is a flowchart illustrating a substrate processing method according to the third embodiment.

First, a substrate having a poly silicon film as a silicon-containing film that is an etching target is etched by supplying, for example, a HF+F₂ gas as a fluorine-containing gas to an etching apparatus (step S21).

Next, the end point of the etching process is detected by monitoring light emission of SiF by a light emission monitoring unit installed in an exhauster of a chamber of the etching apparatus (step S22).

The end point detection is performed by a process (step S22-1) of guiding an exhaust gas, which includes a SiF₄ gas and is a gas exhausted from the chamber of the etching apparatus, to the light emission monitoring unit, and in a process (step S22-2) of monitoring light emission of SiF in a state in which a measurement environment is set to be an Ar gas atmosphere. In detail, the Ar gas is used as a purge gas of the chamber, and the exhaust gas including the SiF₄ gas formed during the etching process is guided into a container of the light emission monitoring unit by using the Ar gas as a carrier gas of the light emission monitoring unit. Then, the guided gas is excited by plasma and a light emission analysis of the excited gas is performed. By setting the measurement environment to be the Ar gas atmosphere as described above, the light emission of SiF formed by exciting the SiF₄ gas, which is included in the exhaust gas, by plasma can be monitored.

When the etching reaction does not end, the SiF₄ gas is discharged and the light emission of SiF is detected. On the contrary, when the etching reaction ends, the SiF₄ gas is not discharged and no light emission of SiF is detected. Accordingly, the end of the etching process can be detected by confirming that there is no light emission of SiF.

In the end point detection, the light emission of SiF is continuously monitored, and a time point at which the intensity of the light emission becomes zero may be determined as the end point. The monitoring may be started at the start of the etching process, or may be started after lapse of a desired period of time from the start of the etching process. Alternatively, the end point detection may be performed by recognizing a time until the etching process ends in advance, and monitoring the light emission of the SiF after lapse of the time or lapse of the time plus a to confirm that there is no light emission of SiF. When the light emission of SiF is detected at the time of the monitoring, a countermeasure of, for example, extending the etching time may be carried out.

In the present embodiment, similarly to the first embodiment, a gas having a volume % of an Ar gas greater than 87% may be used as a carrier gas for use in the light emission analysis, and the environment under which the light emission is measured may be an Ar gas atmosphere in which the volume % of the Ar gas is greater than 87%. More specifically, the Ar gas only (100% Ar) may be used.

### <Processing System>

Next, an example of a processing system used for carrying out the substrate processing method according to the embodiments will be described.

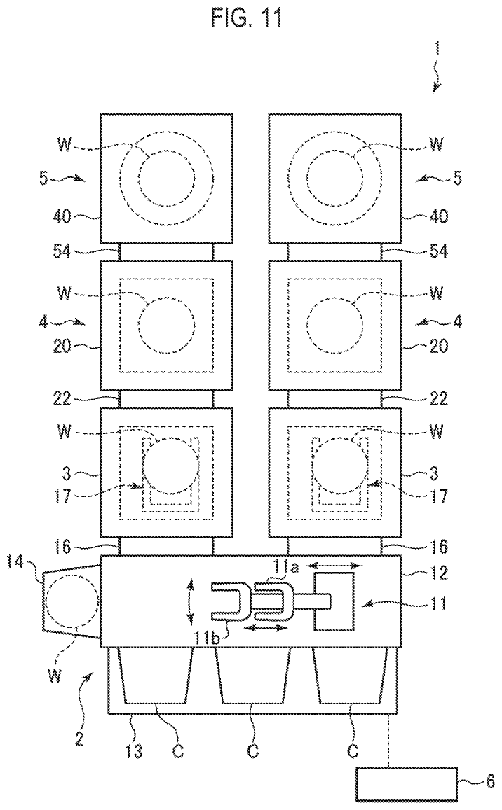

FIG. 11 is a schematic diagram illustrating an example of the processing system. The processing system 1 performs the substrate processing method according to the first or second embodiment described above, with respect to a wafer W in which a SiO₂ film is formed.

The processing system 1 includes a loader/unloader 2, two load lock chambers (L/L) 3, two PHT apparatuses 4, two COR apparatuses 5, and a controller 6.

The loader/unloader 2 loads and unloads the wafer W. The loader/unloader 2 has a transfer chamber (L/M) 12. A first wafer transfer mechanism 11 that transfers the wafer W is installed in the interior of the transfer chamber 12. The first wafer transfer mechanism 11 has two transfer arms 11a and 11b that hold the wafer W in a substantially horizontal position. A stage 13 is provided on a lengthwise side of the transfer chamber 12, and is configured such that, for example, three carriers C, each of which accommodates a plurality of wafers W arranged therein, are connected to the stage 13. Further, an orienter 14, which performs an alignment of the wafer W by rotating the wafer W and optically obtaining eccentricity, is installed at a location adjacent to the transfer chamber 12.

In the loader/unloader the wafer W is held by the transfer arms 11a and 11b, and is transferred to a desired location by a linear movement in a horizontal plane and/or an upward or downward movement driven by the first wafer transfer mechanism 11. Further, the wafer W is loaded and unloaded as the transfer arms 11a and 11b advance and retreat with respect to the carrier C mounted on the stage 13, the orienter 14, and the load lock chambers 3.

The two load lock chambers (IA) 3 are located adjacent to the loader/unloader 2. Each of the load lock chambers 3 is connected to the transfer chamber 12 via a gate valve 16, A second wafer transfer mechanism 17 that transfers the wafer W is provided in each of the load lock chambers 3. Further, the load lock chambers 3 are configured to be vacuum-evacuated to a desired degree of vacuum.

The second wafer transfer mechanism 17 has an articulated arm structure, and has a peak that holds the wafer W in a substantially horizontal position. In the second wafer transfer mechanism 17, the peak is located in the load lock chamber 3 in a state in which the articulated arm contracts. By expanding the articulated arm, the peak reaches the PHI apparatus 4, and by further expanding the articulated arm, and the peak reaches the COR apparatus 5. Accordingly, the water W can be transferred among the load lock chamber 3, the PHT apparatus 4, and the COR apparatus 5.

The gate valves 16 are provided between the transfer chamber 12 and the load lock chambers (L/L) 3. Further, gate valves 22 are provided between the load lock chambers L/L 3 and the PHT apparatuses 4, and gate valves 54 are provided between the PHT apparatuses 4 and the COR apparatuses 5.

The controller 6 is configured by a computer, and includes a main controller including a CPU, an input device (a keyboard, a mouse, or the like), an output device (a printer or the like), a display device (a display or the like), and a memory device (a storage medium). The main controller controls operations of respective components of the processing system 1. The control of the respective component by the main controller is performed by a process recipe, which is a control program stored in a storage medium (a hard disk, an optical disk, a semiconductor memory, and the like) embedded in the memory device.

### <COR Apparatus>

Next, the COR apparatus 5 will be described.

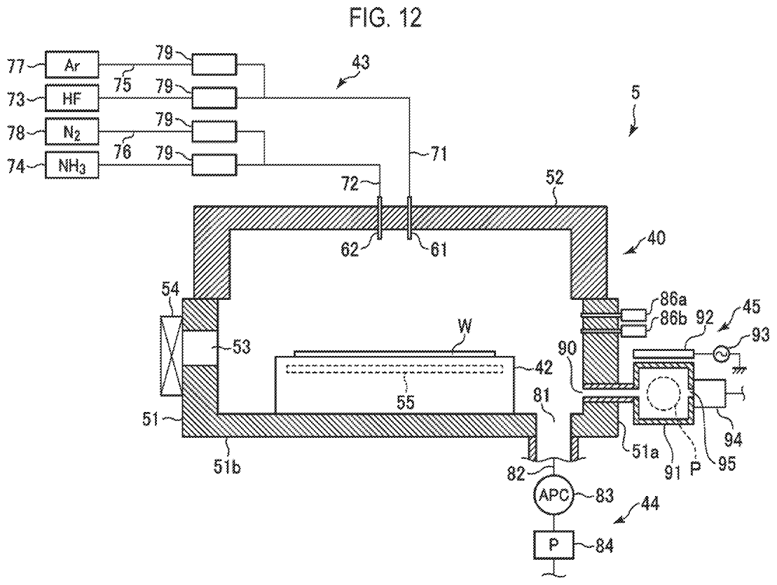

FIG. 12 is a sectional view illustrating the COR apparatus. As illustrated in FIG. 12, the COR apparatus 5 includes a chamber 40 of a sealed structure, and a stage 42 on which the wafer W is mounted in a substantially horizontal position is provided in the interior of the chamber 40. The COR apparatus 5 further includes a gas supply mechanism 43 that supplies an etching gas to the chamber 40, an exhaust mechanism 44 that exhausts a gas from the interior of the chamber 40, and a light emission monitoring unit 45.

The chamber 40 includes a chamber body 51 and a lid 52. The chamber body 51 has a substantially cylindrical side wall 51a and a bottom 51b. The chamber body 51 has an open top which is closed by the lid 52. The side wall 51a and the lid 52 is sealed by a sealing member (not illustrated), securing the air tightness of the interior of the chamber 40. A first gas introduction nozzle 61 and a second gas introduced nozzle 62 are inserted into a ceiling wall of the lid 52 from top toward the interior of the chamber 40.

A loading/unloading port 53, through which the wafer W is delivered to and from the PHT apparatus 4, is formed in the side wall 51a. The loading/unloading port 53 is opened and closed by the gate valve 54.

As a pressure gauge for measuring a pressure of the interior of the chamber 40, two capacitance monometers 86a and 86h for a high pressure and a low pressure, respectively, are installed in the side wall of the chamber 40 such that the capacitance manometers 86a and 86b are inserted into the chamber 40.

The stage 42 has a substantially circular shape in a plan view, and is fixed to the bottom 51b of the chamber 40. A temperature adjuster 55 that adjusts a temperature of the stage 42 is embedded in the stage 42. The temperature adjuster 55 includes, for example, a pipeline through which a temperature adjusting medium (for example, water) circulates. The temperature of the stage 42 is adjusted by heat exchange between the stage 42 and the temperature adjusting medium flowing in the pipeline, whereby a temperature of the wafer W mounted on the stage 42 is controlled. The temperature adjuster 55 may be a heater according to a temperature. A temperature sensor (not illustrated) that detects the temperature of the wafer W is provided in the vicinity of the wafer W mounted on the stage 42, and the temperature of the wafer W is controlled by adjusting, for example, a flow rate of the temperature adjusting medium of the temperature adjuster 55 according to a detection value of the temperature sensor.

The gas supply mechanism 43 has a first gas supply pipe 71 and a second gas supply pipe 72 connected to the first gas introduction nozzle 61 and the second gas introduction nozzle 62, respectively, and further includes a HF gas source 73 and a NH₃ gas source 74 connected to the first gas supply pipe 71 and the second gas supply pipe 72, respectively. Further, a third gas supply pipe 75 is connected to the first gas supply pipe 71, and a fourth gas supply pipe 76 is connected to the second gas supply pipe 72. An Ar gas source 77 and a N₂ gas source 78 are connected to the third gas supply pipeline 75 and the fourth gas supply pipeline 76, respectively. Flow rate controllers 79, which open and close flowpaths and control flow rates, are installed in the first to fourth gas supply pipes 71, 72, 75, and 76. Each of the flow rate controllers 79 includes, for example, an opening/closing valve and a mass flow controller.

A HF gas and an Ar gas are supplied to the interior of the chamber 40 via the first gas supply pipe 71 and the first gas introduction nozzle 61, and a NH₃ gas and a N₂ gas is discharged to the interior of the chamber 40 via the second gas supply pipe 72 and the second gas introduction nozzle 62.

Among the above gases, the HF gas and the NH₃ gas function as a reaction gas, and the Ar gas and the N₂ gas function as a dilution gas (carrier gas) or a purge gas.

In some embodiments, a shower plate may be provided at an upper portion of the chamber 40, and the gases may be supplied in a shower shape through the shower plate.

The exhaust mechanism 44 has an exhaust pipe 82 connected to an exhaust port 81 formed at the bottom 51b of the chamber 40. The exhaust mechanism 44 also has an automatic pressure control (APC) valve 83 installed in the exhaust pipe 82 and configured to control the pressure of the interior of the chamber 40, and a vacuum pump 84 configured to exhausting a gas from the interior of the chamber 40.

The light emission monitoring unit 45 includes a container 91, an inductively coupled plasma (ICP) antenna 92, a high-frequency power source 93, and a light emission analyzer 94. The container 91 communicates with an introduction port 90 formed at a lower portion of the side wall 51a of the chamber 40, and an exhaust gas in the interior of the chamber 40 is guided to the container 91 with the Ar gas as a carrier gas. A high-frequency power is applied from the high-frequency power source 93 to the ICP antenna 92, and an inductively coupled plasma P is formed in the container 91. The light emission analyzer 94 communicates with the container 91 through an observation window 95, and measures light emission of the inductively coupled plasma P in the container 91. The light emission monitoring unit 45 detects an end point of the decomposition reaction of AFS by measuring a spectroscopic intensity of a wavelength (440 nm) of SiF in the light emission spectrum of plasma using the light emission analyzer 94. The light emission monitoring unit 45 is used when the AFS is decomposed in the COR apparatus 5.

In the COR apparatus 5 configured as above, the wafer W is loaded into the interior of the chamber 40 and mounted on the stage 42, and then the wafer W is processed. The COR apparatus 5 may perform both of the COR process and the AFS removal process as in the first embodiment. Alternatively, as in the second embodiment, the COR apparatus may perform the COR process only and the AFS removal process may be performed in the PHT apparatus 4.

When both of the COR process and the AFS removal process are performed in the COR apparatus 5, the pressure of the interior of the chamber 40 may be set to be in a range of 2.666 to 399.9 Pa (20 to 3000 mTorr), and the temperature of the wafer W may be set to be in a range of 20 to 130 degrees C. by the temperature adjuster 55 of the stage 42.

The COR process is performed by supplying the HF gas and the NH₃ gas into the chamber 40 by the gas supply mechanism 43 in a state in which the HF gas and the NH₃ gas are diluted by the Ar gas and the N₂ gas. At this time, flow rates of the gases may be set such that a flow rate of the HF gas is 10 to 2000 sccm, a flow rate of the NH₃ gas is 10 to 2000 sccm, a flow rate of the Ar gas is 10 to 2000 sccm, and a flow rate of the N₂ gas is 10 to 2000 sccm.

As described above, the HF gas and the NH₃ gas are adsorbed to the wafer W, and react with the SiO₂ film on the surface of the wafer W to form AFS.

The AFS removal process is performed after the COR process by vacuum-evacuating the interior of the chamber 40 with the vacuum pump 84 of the exhaust mechanism 44 set to a complete suction state. A vacuum-evacuation time is set in advance according to an amount of adsorbed AFS. The AFS may be removed while purging the interior of the chamber 40 at a pressure of 666.5 Pa (5000 mTorr) or less, with the flow rate of the Ar or the N₂ gas set to 2000 sccm or less. A temperature of the substrate during the AFS removal process may be the same as the temperature of the COR process. Alternatively, the temperature may be increased by 100 to 300 degrees C. such that the removal process may be performed at a higher temperature.

Next, after lapse of a predetermined period of time, the end point of the decomposition reaction of AFS is detected by detecting light emission of SiF using the light emission monitoring unit 45. The chamber 40 is purged using the Ar gas, and the measurement starts at a time point when the pressure is stabilized. During the measurement, the exhaust gas with the Ar gas as a carrier gas is guided to the container 91, an inductively coupled plasma is formed in the container 91 to excite SiF, and the light emission analyzer 94 monitors the light emission of SiF formed by the excitation in a state in which the measurement environment is set to be an Ar gas atmosphere. The end point is detected by confirming that there is no light emission of SiF.

As described above, the COR process, the AFS removal process, and the end point detection may be repeated a plurality of times. In this case, the end point detection may not be performed at all timings, and may be performed at arbitrary timings.

Further, the chamber 40 may be purged after the vacuum-evacuation in the AFS removal process, and the end point detection may be performed after the purge process. When the purge process is performed using an Ar gas, the end point detection may be performed immediately after the purge process ends. The COR process, the AFS removal process, the purge process, and the end point detection may be repeated a plurality of times. In this case, the end point detection may not be performed at all timings, and may be performed at arbitrary timings.

When the AFS removal process is performed by the PHT apparatus 4, the light emission monitoring unit 45 may not be provided in the COR apparatus 5.

### <PHT Apparatus>

Next, the PHT apparatus 4 will be described.

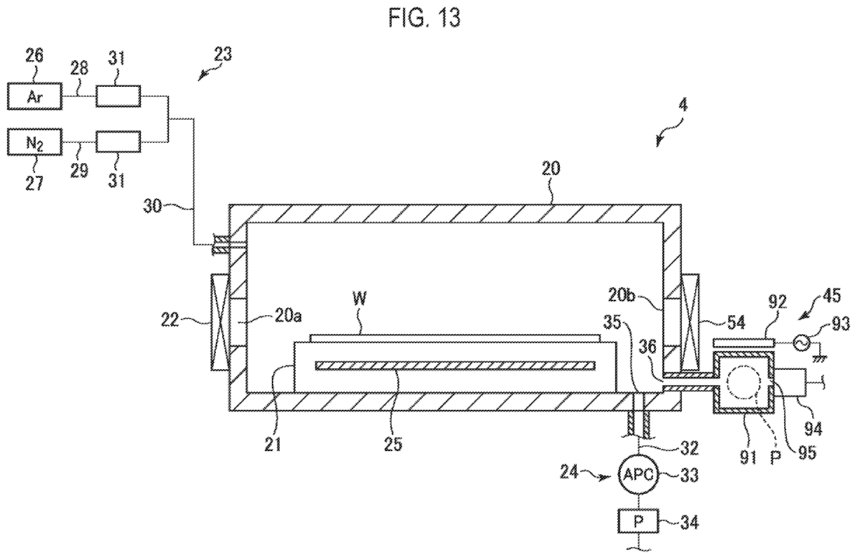

FIG. 13 is a sectional view illustrating the PHT apparatus 4. As illustrated in FIG. 13, the PHT apparatus 4 includes a chamber 20 of a sealed structure, and a stage 21 on which the wafer W is mounted in a substantially horizontal position is provided in the interior of the chamber 20. Further, the PHT apparatus 4 includes a gas supply mechanism 23 that supplies a purge gas to the chamber 20, an exhaust mechanism 24 that exhausts a gas from the interior of the chamber 20, and the light emission monitoring unit 45 configured as above.

A loading/unloading port 20a, through which a wafer is delivered to and from the load lock chamber 3, is formed on a side of the chamber 20 facing the load lock chamber 3. The loading/unloading port 20a is opened and closed by the gate valve 22. A loading/unloading port 20b, through which the wafer W is delivered to and from the etching apparatus (COR apparatus) 5, is formed on a side of the chamber facing the etching apparatus 5. The loading/unloading port 20h is be opened and closed by the gate valve 54.

The stage 21 has a substantially circular shape in a plan view, and is fixed to the bottom of the chamber 20. A heater 25 is embedded in the stage 21, and the wafer W is heated by the heater 25.

The gas supply mechanism 23 includes an Ar gas source 26 and a N₂ gas source 27. A pipe 28 is connected to the Ar gas source 26, and a pipe 29 is connected to the N₂ gas source 27. The pipes 28 and 29 join to a merging pipe 30 connected to the chamber 20. Thus, the Ar gas and the N₂ gas are supplied to the interior of the chamber 20. A flow rate controller 31, which opens and closes a flowpath and controls a flow rate, is installed in each of the pipes 28 and 29. The flow rate controller 31 includes, for example, an opening/closing valve and a mass flow controller.

The exhaust mechanism 24 includes an exhaust pipe 32 connected to an exhaust port 35 formed at a bottom of the chamber 20. The exhaust mechanism 24 further includes an automatic pressure control (APC) valve 33 installed in the exhaust pipe 32 and configured to control the pressure of the interior of the chamber 20, and a vacuum pump 34 configured to exhaust a gas from the interior of the chamber 20.

The light emission monitoring unit 45 communicates with an introduction port 36 formed at a lower portion of the side wall of the chamber 20, and has a configuration similar to that of the light emission monitoring unit 45 provided in the COR apparatus 5.

In the PHT apparatus 4 configured as above, the wafer W having been subjected to the COR process in the COR apparatus 5 is loaded into the chamber 20 and mounted on the stage 21, and the AFS is removed.

In a state in which the pressure of the chamber 20 is set to be 1.333 to 666.6 Pa (10 to 5000 mTorr) and the heating temperature of the substrate is set to be 100 to 300 degrees C., the AFS is decomposed while the purge gas is supplied. Thus, the decomposition gas is discharged from the chamber of the PHT apparatus.

Then, the light emission monitoring unit 45 detects an end point of the decomposition reaction of AFS, The chamber 20 is purged using the Ar gas, and the measurement starts at a time point when the pressure is stabilized. During the measurement, the exhaust gas with the Ar gas as a carrier gas is guided to the container 91, an inductively coupled plasma is formed in the container 91 to excite SiF, and the light emission of SiF formed by the excitation is monitored. The end point is detected by confirming that there is no light emission of SiF.

In the end point detection, the light emission of SiF may be continuously monitored, and a time point when the intensity of the light emission becomes zero may be determined as the end point. In this case, the monitoring may start at the start of the heating process of the PHT apparatus 4, or may start after lapse of a desired period of time from the start of the heating process. Alternatively, the end point detection may be performed by monitoring the light emission of SiF after lapse of a predetermined period of time and confirming that there is no light emission of SiF.

When the light emission of SiF for use in detecting the end point is not monitored, the purge gas of the PHT apparatus 4 may be a N₂ gas.

When the AFS removal process is performed by the COR apparatus 5, residues after the removal process is removed in the PHT apparatus 4. In this case, it is not necessary to provide the light emission monitoring unit 45 in the PHT apparatus 4.

In the third embodiment, a processing system in which the COR apparatus 5 is replaced by an etching apparatus having a gas supply mechanism that supplies a HF gas and a F₂ gas as a fluorine-containing gas, for example, may be used, for example. In this case, since it is not necessary to decompose the reaction product, the PHT apparatus 4 is used for removing residues.

### <Other Applications>

Although the embodiments have been described until now, the embodiments disclosed herein are only illustrative and are not restrictive. Omissions, replacements, and modifications may be made in various forms without departing from the scope of the attached claims and the spirit thereof.

For example, the apparatuses of the embodiments are simply examples, and apparatuses of various configurations may be used. Further, although it has been illustrated that a semiconductor wafer is used as the substrate to be processed, the substrate is not limited to the semiconductor wafer but may be another substrate, such as a flat panel display (FPD) substrate that is a representative substrate for a liquid crystal display (LCD) substrate, or a ceramics substrate. In addition, although the end point detection by monitoring SiF has been described as an example in the embodiments, the present disclosure is not limited thereto.

According to the present disclosure, in a reaction that forms a SiF₄ gas, light emission of SiF can be monitored with a high precision.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of monitoring light emission of SiF in a reaction that forms a SiF₄ gas; the method comprising:
guiding an exhaust gas, which includes the SiF₄ gas formed in the reaction, together with an Ar gas to a light emission monitoring unit; and
monitoring the light emission of SiF in a state in which a measurement environment of the light emission monitoring unit is set to be an Ar gas atmosphere.

2. The method of claim 1, wherein the reaction that forms the SiF₄ gas is a decomposition reaction of ammonium fluorosilicate formed on a surface of a substrate.

3. The method of claim 2, wherein the ammonium fluorosilicate is a reaction product formed when a silicon-based oxide film formed on the substrate is etched by a fluorine-containing gas.

4. The method of claim 3, wherein the fluorine-containing gas includes a HF gas and a NH₃ gas.

5. The method of claim 4, wherein the Ar gas atmosphere is an atmosphere in which a volume % of the Ar gas is greater than 87%.

6. The method of claim 1, wherein the reaction that forms the SiF₄ gas is an etching reaction when a silicon-containing film is etched by a fluorine-containing gas.

7. The method of claim 6, wherein the etching reaction is an etching reaction when a silicon film is etched by a HF gas and a F₂ gas.

8. The method of claim 1, wherein the Ar gas atmosphere is an atmosphere in which a volume % of the Ar gas is greater than 87%.

9. The method of claim 1, wherein the light emission monitoring unit excites the SiF₄ gas by a plasma to form SiF, and monitors the light emission of the SiF.

10. The method of claim 1, wherein the monitoring the light emission of SW further includes determining, as an end point of the reaction, a time point when the light emission monitoring unit detects that the light emission of SiF is equal to or less than a threshold.

11. The method of claim 10, wherein a period of time until the end point of the reaction is determined in advance, and the light emission of SiF is monitored after lapse of the period of time.

12. The method of claim 10, wherein the light emission of SiF is continuously monitored, and a time point when an intensity of the light emission becomes equal to or less than the threshold is determined as the end point of the reaction.

13. A substrate processing method comprising:
forming a reaction product, which forms a SiF₄ gas by a decomposition reaction, on a substrate by etching a silicon-containing substance formed on the substrate using a fluorine-containing gas;
decomposing the reaction product; and
monitoring light emission of SiF during the decomposing the reaction product,
wherein the monitoring the light emission of SiF₄ comprises:
guiding an exhaust gas, which includes the SiF₄ gas formed by the decomposition reaction, together with an Ar gas to a light emission monitoring unit; and
monitoring the light emission of SiF in a state in which a measurement environment of the light emission monitoring unit is set to be an Ar gas atmosphere.

14. The method of claim 13, wherein the silicon-containing substance is a silicon-based oxide film, the fluorine-containing gas includes a HF gas and a NH₃ gas, and the reaction product is ammonium fluorosilicate.

15. The method of claim 13, wherein the forming the reaction product and the decomposing the reaction product are performed in a chamber of the same apparatus, and the decomposing the reaction product is performed through vacuum-evacuation, and
wherein the guiding the exhaust gas includes purging an interior of the chamber using the Ar gas after the vacuum-evacuation, and guiding the exhaust gas from the chamber to the light emission monitoring unit.

16. The method of claim 15, wherein the forming the reaction product and the decomposing the reaction product are repeatedly performed, and
wherein the monitoring the light emission of SiF further includes detecting an end point of the decomposition reaction at an arbitrary timing after the decomposing of the reaction product ends.

17. The method of claim 16 further comprising, after the decomposing the reaction product and before the detecting the end point, purging the interior of the chamber.

18. The method of claim 17 wherein the forming the reaction product, the decomposing the reaction product, the purging the interior of the chamber are repeatedly performed, and wherein the detecting the end point is performed at an arbitrary timing after the purging the interior of the chamber ends.

19. The method of claim 13, wherein the forming the reaction product is performed in a chamber of a reaction apparatus; and the decomposing the reaction product is performed by heating the substrate by a heating apparatus provided separately from the reaction apparatus, and
wherein the guiding the exhaust gas includes guiding an exhaust gas from a chamber of the heating apparatus to the light emission monitoring unit.

20. A substrate processing apparatus comprising:
a chamber that accommodates a substrate having a silicon-containing substrate;
a stage, which is installed in the chamber and on which the substrate is mounted;
a temperature adjuster configured to adjust a temperature of the substrate mounted on the stage;
a gas supplier configured to supply a fluorine-containing gas and an Ar gas which form an etching gas;
an exhauster configured to exhaust an exhaust gas from an interior of the chamber; and
a light emission monitoring unit configured to monitor light emission of the exhaust gas, which includes a SiF₄ gas and exhausted from the chamber,
wherein the light emission monitoring unit comprises:
a container, to which the exhaust gas including the SiF₄ gas is guided;
a plasma forming mechanism configured to form a plasma in the container; and
a light emission analyzer configured to measure light emission of the plasma, and
wherein the light emission monitoring unit monitors the light emission of the exhaust gas by measuring light emission of SiF by the light emission analyzer in an Ar gas atmosphere, the Ar gas atmosphere being set by guiding the exhaust gas, which includes the SiF₄ gas, together with the Ar gas to the interior of the container after the interior of the chamber is purged by supplying the Ar gas from the gas supplier to the interior of the chamber.
